(19) United States
(12) Patent Application Publication
(10) Pub. No.: US 2025/0039611 A1
(43) Pub. Date: Jan. 30, 2025

(54) MEMS ACOUSTIC ELEMENT

(71) Applicant: Murata Manufacturing Co., Ltd., Nagaokakyo-shi (JP)

(72) Inventors: Ryosuke NIWA, Nagaokakyo-shi (JP); Shinsuke IKEUCHI, Nagaokakyo-shi (JP); Hiroshi MATSUBARA, Nagaokakyo-shi (JP)

(21) Appl. No.: 18/913,111

(22) Filed: Oct. 11, 2024

Related U.S. Application Data
(63) Continuation of application No. PCT/JP2023/005949, filed on Feb. 20, 2023.

(30) Foreign Application Priority Data
Jun. 22, 2022 (JP) 2022-100158

(51) Int. Cl. H04R 17/02; B81B 7/00; B81C 1/00

(52) U.S. Cl. CPC H04R 17/02; B81B 7/0016; B81C 1/00825; B81B 2201/0257; B81B 2203/0127; B81B 2203/04; B81B 2207/012; B81C 2203/0154; B81C 2203/0792; H04R 2201/003

(57) ABSTRACT

A device may include a first substrate provided with a first through hole. A device may include a second substrate arranged adjacent to the first through hole and configured to partially overlap with the first substrate on a second side of the first substrate. A device may include a vibration layer arranged adjacent to and overlap with the first substrate on a first side of the first substrate opposite the second substrate and configured to stride across the first through hole. A device may include a resin layer disposed to overlap with a portion of the vibration layer overlapping with the first substrate. A device may include a first pad electrode. A device may include a second pad electrode. A device may include the first pad electrode and the second pad electrode being disposed on a surface of the resin layer opposite from the vibration layer.

### CROSS REFERENCE TO RELATED APPLICATIONS

This application is a continuation of International Application No. PCT/JP2023/005949, filed Feb. 20, 2023, which claims priority to Japanese Patent Application No. 2022-100158, filed Jun. 22, 2022, the entire contents of each of which are hereby incorporated in their entirety.

### TECHNICAL FIELD

The present disclosure relates to a Micro Electronic Mechanical Systems (“MEMS”) acoustic element and a method of manufacturing the MEMS acoustic element.

### BACKGROUND

Japanese Patent Laid-Open No. 2020-159836 (hereinafter “JP '836”) discloses a sensor module. The sensor module includes a substrate, a sensor chip and a controller IC mounted on the substrate, and a cap that covers the sensor chip and the controller IC.

Further, Japanese Patent Laid-Open No. 2010-21225 (hereinafter “JP '225”) discloses a silicon microphone as an electronic component. The silicon microphone includes a substrate, a MEMS chip, and an electronic circuit chip. The MEMS chip and the electronic circuit chip are connected by wires. The MEMS chip and the electronic circuit chip are sealed with a primary mold resin. A silicone resin is applied as a buffer material around a diaphragm disposed on an upper surface of the MEMS chip. The buffer material prevents any protrusion of a transfer mold from directly contacting the diaphragm of the MEMS chip. Accordingly, it is possible to prevent the MEMS chip from being damaged during the manufacturing process. A sound collector is formed in a secondary mold resin so as to face an opening of the primary mold resin.

In the configuration disclosed in JP '835, considering the positional accuracy of the cap during the mounting operation, the cap needs to be designed considerably larger than the sensor chip, which considerably increases the size of the entire sensor module. In addition, if the cap is made of metal, and in fact the cap must be manufactured by using a mold, the manufacturing cost increases accordingly.

In the configuration disclosed in JP '225, it is required to provide a space for wires that connect the MEMS chip and the electronic circuit chip. This inevitably increases the size of the silicon microphone. In addition, since the MEMS chip is subjected to a pressing force from the mold during resin molding, the MEMS chip must be made robust. Making the MEMS chip robust will increase the size and the manufacturing cost of the MEMS chip, and decrease the degree of design freedom thereof.

In the configuration disclosed in JP '225, the electrode is disposed on the bottom surface of the substrate, whereas the opening of the sound collector is formed on a surface of the substrate opposite to the electrode. Therefore, it is difficult to align the silicon microphone with respect to the housing.

### SUMMARY OF INVENTION

Therefore, an object of the present disclosure is to provide a MEMS acoustic element that is advantageous for miniaturization, does not require an expensive metal cap, and is easily aligned during mounting.

In order to achieve the above-mentioned object, an MEMS acoustic element according to the present disclosure includes: a first substrate provided with a first through hole; a second substrate disposed to close the first through hole and configured to at least partially overlap with the first substrate; a vibration layer disposed to overlap with the first substrate on a side of the first substrate opposite to the second substrate and configured to stride across the first through hole; a resin layer disposed to overlap with a portion of the vibration layer overlapping with the first substrate; a first pad electrode; and a second pad electrode. The first pad electrode and the second pad electrode are disposed on a surface of the resin layer distant from the vibration layer. The vibration layer includes a piezoelectric layer, a first electrode layer disposed to overlap with a surface of the piezoelectric layer distant from the first substrate, and a second electrode layer disposed to overlap with a surface of the piezoelectric layer close to the first substrate. The first pad electrode is electrically connected to the first electrode layer. The second pad electrode is electrically connected to the second electrode layer.

In some aspects, the techniques described herein relate to a MEMS acoustic element including: a first substrate provided with a first through hole; a second substrate arranged adjacent to the first through hole and configured to partially overlap with the first substrate on a second side of the first substrate; a vibration layer arranged adjacent to and overlap with the first substrate on a first side of the first substrate opposite the second substrate and the second side of the first substrate, and configured to stride across the first through hole; a resin layer disposed to overlap with a portion of the vibration layer overlapping with the first substrate; a first pad electrode; and a second pad electrode, the first pad electrode and the second pad electrode being disposed on a surface of the resin layer opposite from the vibration layer.

In some aspects, the techniques described herein relate to a method of manufacturing a MEMS acoustic element including: providing a first substrate with a first through hole and having a top side and a bottom side, the top side above the bottom side and on opposite sides of the first substrate; disposing a second substrate below the first substrate and arranged to partially overlap a portion of the bottom side of the first substrate; disposing a vibration layer above the top side of first substrate and arranged to partially overlap, and arranged to stride across the first through hole; disposing a resin layer above the vibration layer and arranged to overlap with a portion of the vibration layer which overlaps with the first substrate; disposing a first pad electrode above the vibration layer; and disposing a second pad electrode above the vibration layer, wherein the first pad electrode and the second pad electrode being disposed on a top surface of the resin layer.

According to the present disclosure, it is possible to realize a MEMS acoustic element which is advantageous for miniaturization, does not require an expensive metal cap, and is easily aligned during mounting.

### BRIEF DESCRIPTION OF DRAWINGS

In the descriptions that follow, like parts are marked throughout the specification and drawings with the same numerals, respectively. The drawings are not necessarily drawn to scale and certain drawings may be shown in exaggerated or generalized form in the interest of clarity and conciseness. The disclosure itself, however, as well as a mode of use, further features and advances thereof, will be understood by reference to the following detailed description of illustrative implementations of the disclosure when read in conjunction with reference to the accompanying drawings, wherein:

FIG. 1 is a plan view illustrating a MEMS acoustic element in accordance with aspects of the present disclosure;

FIG. 2 is a schematic cross-sectional view illustrating the MEMS acoustic element in accordance with aspects of the present disclosure;

FIG. 3 is an explanatory diagram illustrating a first step of a manufacturing method of the MEMS acoustic element in accordance with aspects of the present disclosure;

FIG. 4 is an explanatory diagram illustrating a second step of the manufacturing method of the MEMS acoustic element in accordance with aspects of the present disclosure;

FIG. 5 is an explanatory diagram illustrating a third step of the manufacturing method of the MEMS acoustic element in accordance with aspects of the present disclosure;

FIG. 6 is an explanatory view illustrating that solder bumps are disposed after the third step of the manufacturing method of the MEMS acoustic element in accordance with aspects of the present disclosure;

FIG. 7 is an explanatory diagram illustrating a fourth step of the manufacturing method of the MEMS acoustic element in accordance with aspects of the present disclosure;

FIG. 8 is an explanatory diagram illustrating a fifth step of the manufacturing method of the MEMS acoustic element in accordance with aspects of the present disclosure;

FIG. 9 is an explanatory diagram illustrating a first step of a manufacturing method of a modified example of the MEMS acoustic element in accordance with aspects of the present disclosure;

FIG. 10 is an explanatory diagram illustrating a second step of the manufacturing method of the modified example of the MEMS acoustic element in accordance with aspects of the present disclosure;

FIG. 11 is an explanatory diagram illustrating a third step of the manufacturing method of the modified example of the MEMS acoustic element in accordance with aspects of the present disclosure;

FIG. 12 is an explanatory diagram illustrating a fourth step of the manufacturing method of the modified example of the MEMS acoustic element in accordance with aspects of the present disclosure;

FIG. 13 is an explanatory diagram illustrating a fifth step of the manufacturing method of the modified example of the MEMS acoustic element in accordance with aspects of the present disclosure;

FIG. 14 is a schematic cross-sectional view illustrating a MEMS acoustic element in accordance with aspects of the present disclosure;

FIG. 15 is an explanatory diagram illustrating a first step of a manufacturing method of the MEMS acoustic element in accordance with aspects of the present disclosure;

FIG. 16 is an explanatory diagram illustrating a second step of the manufacturing method of the MEMS acoustic element in accordance with aspects of the present disclosure;

FIG. 17 is a schematic cross-sectional view illustrating a MEMS acoustic element in accordance with aspects of the present disclosure;

FIG. 18 is a schematic cross-sectional view illustrating a MEMS acoustic element in accordance with aspects of the present disclosure;

FIG. 19 is an explanatory diagram illustrating a first step of a manufacturing method of the MEMS acoustic element in accordance with aspects of the present disclosure;

FIG. 20 is an explanatory diagram illustrating a second step of the manufacturing method of the MEMS acoustic element in accordance with aspects of the present disclosure; and

FIG. 21 is an explanatory diagram illustrating a third step of the manufacturing method of the MEMS acoustic element in accordance with aspects of the present disclosure.

### DETAILED DESCRIPTION

Hereinbelow, aspects of the present disclosure will be described. In a following description of the drawings, the same or similar components will be represented with use of the same or similar reference characters. The drawings are exemplary, sizes or shapes of portions are schematic, and technical scope of the present disclosure should not be understood with limitation to the aspects.

The dimensional ratios illustrated in the drawings do not necessarily faithfully represent the actual dimensions, and the dimensional ratios may be exaggerated for the purpose of explanation. In the following description, when referring to the concept of top or bottom, it does not necessarily mean absolute top or bottom, but may mean relative top or bottom in the illustrated posture.

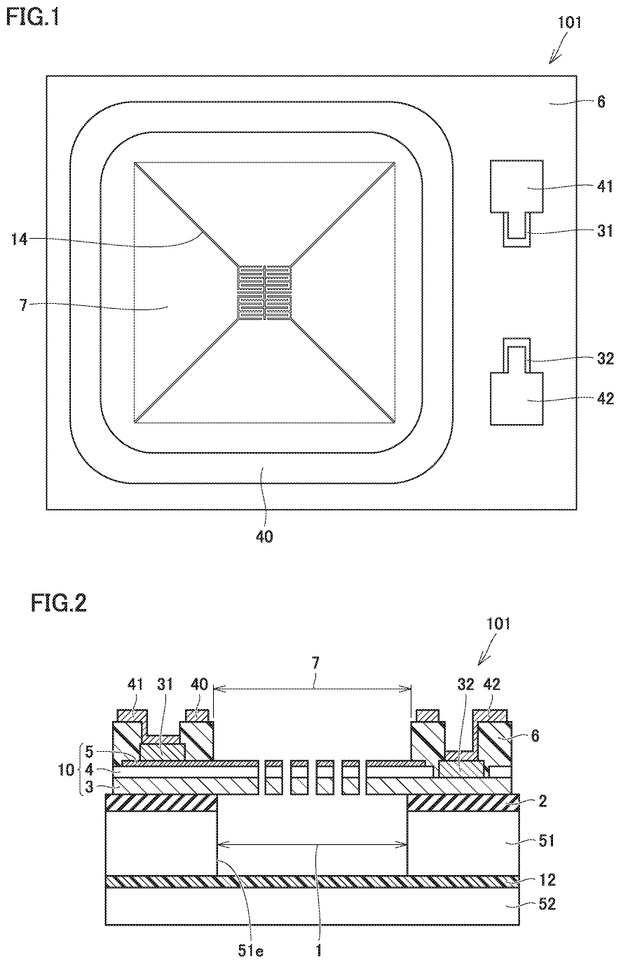

A MEMS acoustic element according to an aspect of the present disclosure will be described with reference to FIGS. 1 and 2. FIG. 1 is a plan view illustrating a MEMS acoustic element 101 according to an aspect of the present disclosure. FIG. 1 illustrates a large acoustic hole 7 in the center. In FIG. 1, the acoustic hole 7 has a square shape. FIG. 2 is a schematic cross-sectional view illustrating the MEMS acoustic element 101. In FIG. 2, portions that may not appear in the same cross-section are simultaneously illustrated in one cross-sectional view for the purpose of explanation.

The MEMS acoustic element 101 includes a first substrate 51 provided with a first through hole 51e, a second substrate 52 disposed to close the first through hole 51e and configured to at least partially overlap with the first substrate 51, a vibration layer 10 disposed to overlap with the first substrate 51 on a side of the first substrate 51 opposite to the second substrate 52 and configured to stride across the first through hole 51e, a resin layer 6 disposed to overlap with a portion of the vibration layer 10 overlapping with the first substrate 51, a first pad electrode 41, and a second pad electrode 42. The resin layer 6 is made of, for example, polyimide resin.

The first pad electrode 41 and the second pad electrode 42 are disposed on a surface of the resin layer 6 distant from the vibration layer 10. The vibration layer 10 includes a piezoelectric layer 4, an upper electrode layer 5 (a first electrode layer) is disposed to overlap with a surface of the piezoelectric layer 4 distant from the first substrate 51, and a lower electrode layer 3 (a second electrode layer) is disposed to overlap with a surface of the piezoelectric layer 4 close to the first substrate 51.

The first pad electrode 41 is electrically connected to the upper electrode layer 5 (the first electrode layer). The second pad electrode 42 is electrically connected to the lower electrode layer 3 (the second electrode layer). At least a part of the piezoelectric layer 4 is sandwiched between the upper electrode layer 5 and the lower electrode layer 3. More specifically, a substantial part of the piezoelectric layer 4 is sandwiched between the upper electrode layer 5 and the lower electrode layer 3.

As illustrated in FIG. 1, a part of the vibration layer 10 is visible through the acoustic hole 7. The vibration layer 10 is formed with a slit 14 in a predetermined pattern. As illustrated in FIG. 1, the slit 14 may include a meander pattern in a central portion of the vibration layer 10. The slit 14 illustrated in FIG. 1 is merely an example. In FIG. 2, the slit 14 is illustrated in a greatly simplified manner for the purpose of explanation. The same applies to the following cross-sectional views.

More preferably, the MEMS acoustic element 101 includes a ring-shaped metal layer 40 disposed on a surface of the resin layer 6 distant from the vibration layer 10 and configured to surround a projection region of the first through hole 51e.

According to an aspect of the present disclosure, although it is not necessary to implement a cap, a wire or the like, the MEMS acoustic element can be made smaller in size. In particular, since an expensive metal cap is not implemented, the MEMS acoustic element can be manufactured at a lower cost. As described above, according to an aspect of the present disclosure, it is possible to provide a MEMS acoustic element which is advantageous for miniaturization, does not require an expensive metal cap, and is easily aligned during mounting.

Preferably, in one aspect, the MEMS acoustic element 101 includes the ring-shaped metal layer 40 disposed to surround the projection region of the first through hole 51e on the surface of the resin layer 6 distant from the vibration layer 10, and thereby the MEMS acoustic element can be mounted using the ring-shaped metal layer 40. Although in one aspect, it is described that the MEMS acoustic element includes the ring-shaped metal layer 40, this is merely an example, and the MEMS acoustic element may be configured without the ring-shaped metal layer 40.

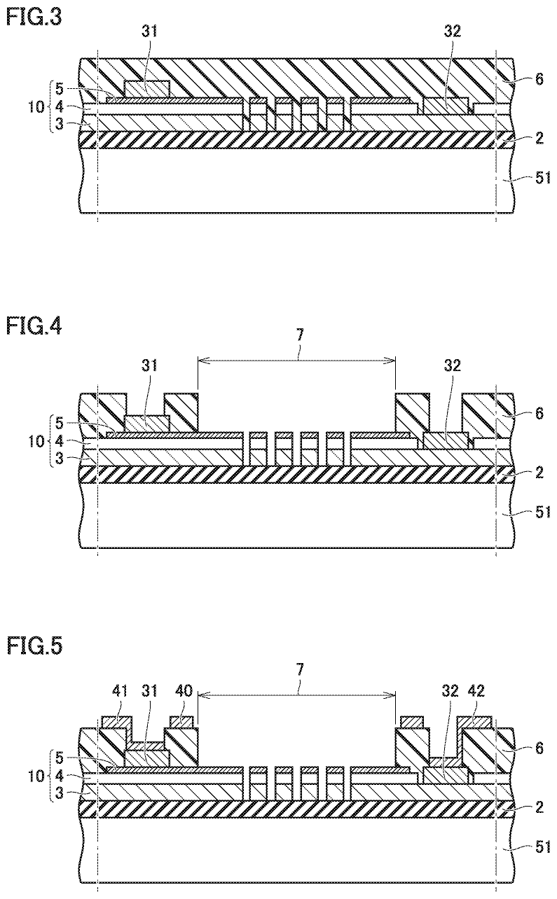

A manufacturing method of the MEMS acoustic element 101 according to the present disclosure will be described with reference to FIGS. 3 to 8.

In the present disclosure, in order to collectively obtain a plurality of MEMS acoustic elements, each step of the manufacturing method is performed using a substrate assembly having a size equivalent to a plurality of MEMS acoustic elements instead of a size equivalent to a single MEMS acoustic element.

As illustrated in FIG. 3, an oxide film 2 is formed on the upper surface of the first substrate 51, and a silicon layer is formed on the upper surface of the oxide film 2 as the lower electrode layer 3, then a piezoelectric layer 4, a metal layer which serves as the upper electrode layer 5, and conductive layers 31 and 32 are formed thereon subsequently, and thereafter, a resin layer 6 is formed so as to cover the entire upper surface. The resin layer 6 is made of, for example, photosensitive polyimide.

As illustrated in FIG. 4, the resin layer 6 is patterned. As a result, at least a part of the conductive layer 31 and a part of the conductive layer 32 are exposed, and the acoustic hole 7 is formed.

As illustrated in FIG. 5, a ring-shaped metal layer 40, a first pad electrode 41, and a second pad electrode 42 are formed. These may be formed by forming a metal film by plating or the like so as to cover the entire upper surface of the resin layer 6 or the like, and then patterning the metal film.

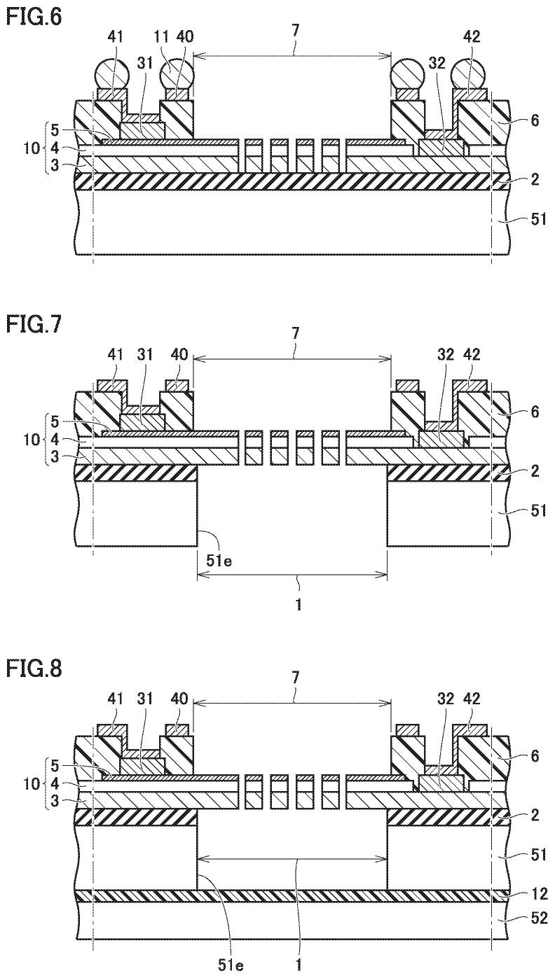

As illustrated in FIG. 6, a conductive connection member 11 may be disposed on the ring-shaped metal layer 40, the first pad electrode 41, and the second pad electrode 42. The conductive connection member 11 is, for example, a solder bump. The conductive connection member 11, i.e., the solder bump may be formed by disposing solder at a desired position by printing and then reflowing the solder. Hereinafter, the description will be continued by assuming that the conductive connection member 11 illustrated in FIG. 6 is not disposed.

As illustrated in FIG. 7, a deep reactive ion etching (DRIE) is performed on the back surface of the first substrate 51 and the oxide film 2. Thus, a cavity 1 is formed. Focusing only on the first substrate 51, it can be said that a first through hole 51e is formed in the first substrate 51.

As illustrated in FIG. 8, a silicon wafer is bonded to the lower surface of the first substrate 51 as the second substrate 52. The second substrate is bonded by resin bonding. In other words, the second substrate 52 is bonded to the first substrate 51 via a resin film 12. The opening of the cavity 1 is closed by the second substrate 52.

After the respective steps have been performed on the substrate assembly, the substrate assembly is subjected to blade dicing from the side of the second substrate 52 to cut the substrate assembly into individual MEMS acoustic elements. Thus, the MEMS acoustic element 101 illustrated in FIGS. 1 and 2 is obtained.

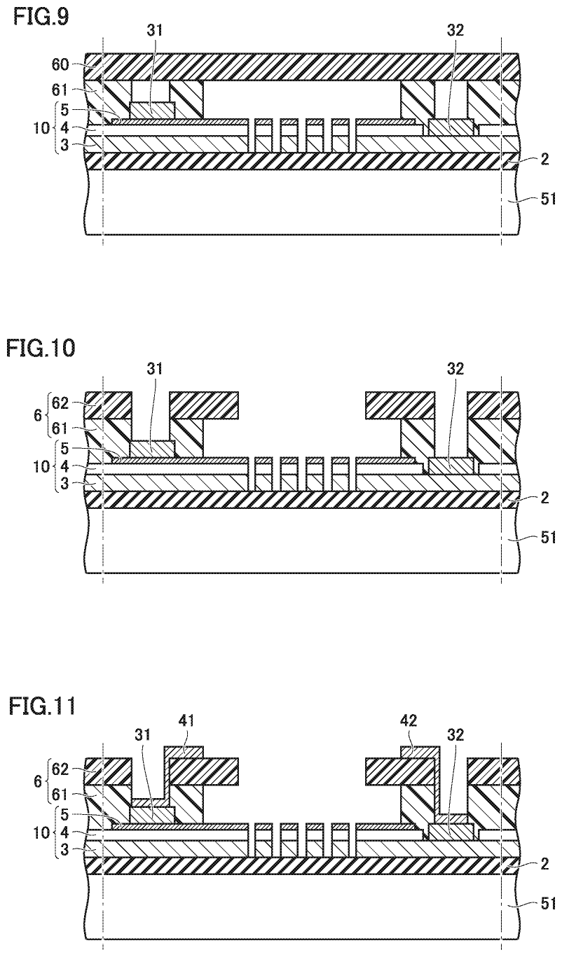

A manufacturing method of a modified example of the MEMS acoustic element according to the present disclosure will be described with reference to FIGS. 9 to 13.

Similar to that illustrated in FIG. 4, and described above, as illustrated in FIG. 9, a resin sheet 60 is attached to the patterned first resin layer 61. The entire upper surface of the patterned first resin layer is covered with the resin sheet 60. The resin sheet 60 may be attached by pressing it with a roller.

As illustrated in FIG. 10, the resin sheet 60 is patterned to form a second resin layer 62. The second resin layer 62 is disposed only on desired areas. The area where the second resin layer 62 is disposed is not limited to the area where the first resin layer 61 is present. The second resin layer 62 may be formed to overhang from the first resin layer 61 in some areas. In the present aspect, a combination of the first resin layer 61 and the second resin layer 62 is referred to as the resin layer 6.

As illustrated in FIG. 11, a first pad electrode 41 and a second pad electrode 42 are formed. These pad electrodes may be formed by forming a metal film by plating or the like so as to cover the entire upper surface of the second resin layer 62 or the like, and then patterning the metal film.

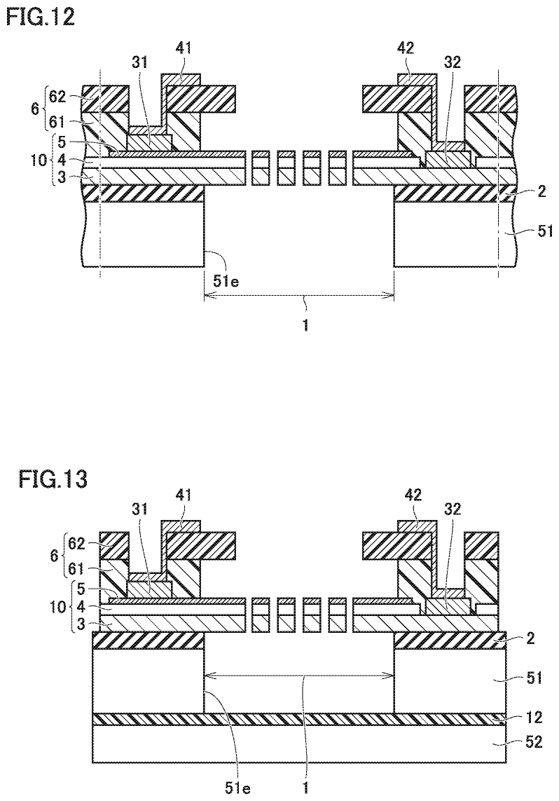

As illustrated in FIG. 12, a DRIE is performed on the back surface of the first substrate 51 and the oxide film 2 to form a cavity 1. The detail thereof is the same as that described with respect to FIG. 7, and as described above.

As illustrated in FIG. 13, a silicon wafer is bonded to the lower surface of the first substrate 51 as the second substrate 52. The detail thereof is the same as that described with respect to FIG. 8.

In this modified example, the resin layer 6 has a two-layer structure of the first resin layer 61 and the second resin layer 62, and the second resin layer 62 has an overhang structure so as to narrow the opening of the acoustic hole 7. With such a configuration, foreign matters are less likely to enter through the acoustic hole 7. Therefore, the vibration layer 10 can be protected from the intrusion of foreign matters. In addition, since the second resin layer 62 has an overhang structure, the vibration layer 10 can be protected from physical impact.

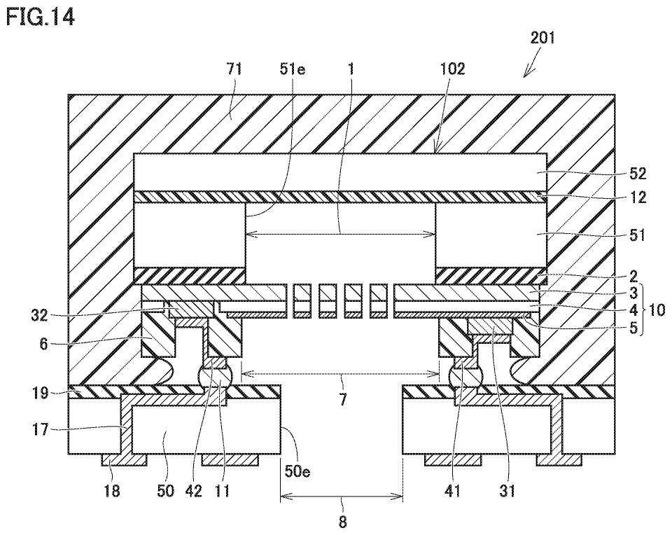

A MEMS acoustic element according to an aspect of the present disclosure will be described with reference to FIG. 14. FIG. 14 is a schematic cross-sectional view illustrating a MEMS acoustic element 201 according to the present aspect. In FIG. 14, as in FIG. 2 and described above, portions that may not appear in the same cross-section are simultaneously illustrated in one cross-sectional view for the purpose of explanation.

The MEMS acoustic element 201 includes a relay substrate 50 and a MEMS acoustic element 102. The MEMS acoustic element 102 is similar to the MEMS acoustic element 101, but is different from the MEMS acoustic element 101 in that it does not include a ring-shaped metal layer 40. The MEMS acoustic element 102 is mounted on the relay substrate 50 through the first pad electrode 41 and the second pad electrode 42.

The relay substrate 50 included in the MEMS acoustic element 201 is provided with a second through hole 50e that corresponds to the first through hole 51e. The second through hole 50e communicates with the acoustic hole 7 of the MEMS acoustic element 102. The first pad electrode 41 and the second pad electrode 42 are each connected to the relay substrate 50 via the conductive connection member 11. An outer peripheral side surface of the resin layer 6, an outer peripheral side surface of the first substrate 51, an outer peripheral side surface of the second substrate 52, and a surface of the second substrate 52 distant from the first substrate 51 are covered with a first coating resin 71.

A plurality of pad electrodes 18 are provided on the lower surface of the relay substrate 50. The upper surface of the relay substrate is covered with an insulating film 19. A plurality of connection conductors 17 are disposed inside the relay substrate 50. The plurality of connection conductors 17 connect the plurality of pad electrodes 18 to the upper surface of the relay substrate 50. The insulating film 19 is provided with several openings. A part of the connection conductor 17 is exposed from each of the openings of the insulating film 19. The first pad electrode 41 and the second pad electrode 42 of the MEMS acoustic element 102 are each connected to the relay substrate via the conductive connection member 11.

In the present disclosure, the same effects can be obtained as those described above. In the present disclosure, the MEMS acoustic element 102 is further protected by being covered with the first coating resin 71 and the relay substrate 50, which increases resistance to physical impact during assembly and use. The MEMS acoustic element 201 can be mounted to other articles via a plurality of pad electrodes 18.

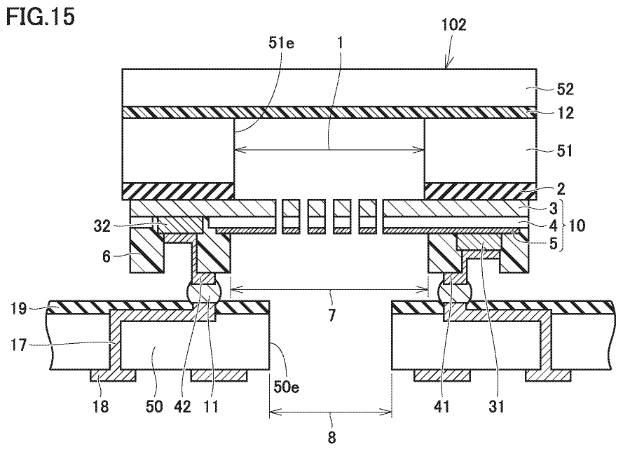

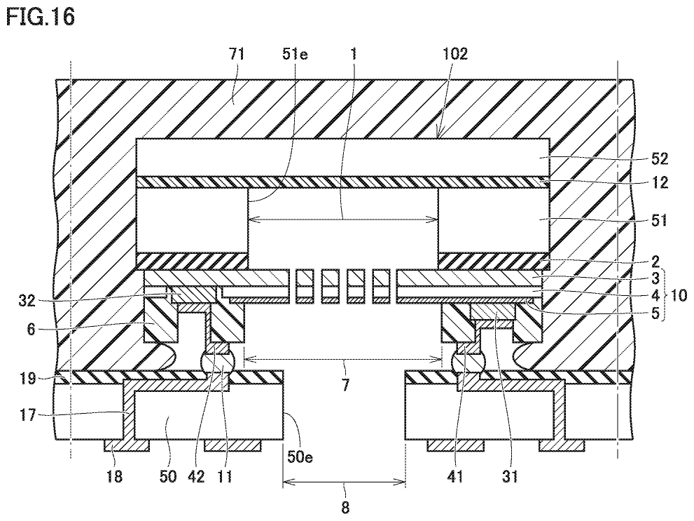

A manufacturing method of the MEMS acoustic element 201 according to the present disclosure will be described with reference to FIGS. 15 to 16.

First, the MEMS acoustic element 102 and the relay substrate 50 are prepared. At this time, the relay substrate 50 is treated as a substrate assembly having a size equivalent to a plurality of products. The upper surface of the relay substrate 50 is formed with an insulating film 19. As illustrated in FIG. 15, the MEMS acoustic element 102 is flip-mounted on the upper surface of the relay substrate 50 with the acoustic hole 7 facing the relay substrate 50. The first pad electrode 41 and the second pad electrode 42 of the MEMS acoustic element 102 are each connected to the relay substrate 50 via the conductive connection member 11. The conductive connection member 11 is, for example, a solder bump.

Next, as illustrated in FIG. 16, the space around the MEMS acoustic element 102 on the upper surface of the relay substrate 50 is covered with the first coating resin 71. The degree of the first coating resin 71 entering into the gap between the MEMS acoustic element 102 and the relay substrate 50 can be controlled by appropriately adjusting the viscosity of the first coating resin 71 and the height of the conductive connecting member 11. The upper surface of the first coating resin 71 is ground so as to lower the height to a necessary level. The substrate assembly is cut into individual products by blade dicing. Thus, the MEMS acoustic element 201 illustrated in FIG. 14 can be obtained.

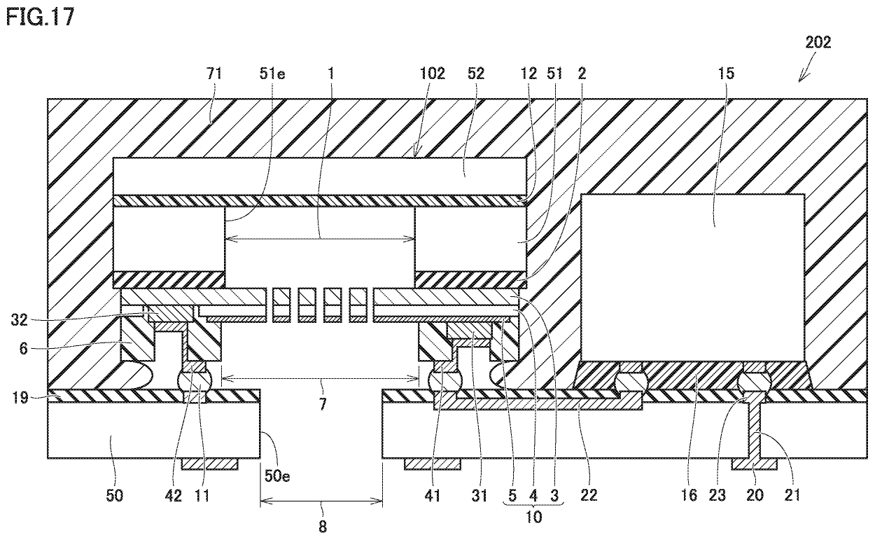

A MEMS acoustic element according to an aspect of the present disclosure will be described with reference to FIG. 17. FIG. 17 is a schematic cross-sectional view illustrating a MEMS acoustic element 202 according to the present disclosure.

The MEMS acoustic element 202 includes a relay substrate 50, an MEMS acoustic element 102, and a circuit chip component 15. The circuit chip component 15 is an integrated circuit (IC). In the MEMS acoustic element 202, the circuit chip component 15 is mounted on a surface of the relay substrate 50 close to the first substrate 51, and the circuit chip component 15 is covered with the first coating resin 71. In other words, the MEMS acoustic element 102 and the circuit chip component 15 are sealed with the first coating resin 71. Connection members such as solder bumps are disposed between the circuit chip component 15 and the relay substrate 50, and an underfill 16 is filled so as to seal these connection members. The underfill 16 is further sealed with the first coating resin 71.

A pad electrode 20 is disposed on the lower surface of the relay substrate 50. A connection conductor 21 is disposed to penetrate the relay substrate 50. The connection conductor 21 connects the pad electrode 20 to an electrode 23 provided on the upper surface of the relay substrate 50. The electrode 23 is exposed from the insulating film 19. A plurality of terminals are provided on the lower surface of the circuit chip component 15. One of the terminals provided on the lower surface of the circuit chip component 15 is connected to the electrode 23 via a solder bump or the like. The other terminals provided on the lower surface of the circuit chip component 15 are electrically connected to the first pad electrode 41 and the second pad electrode 42 of the MEMS acoustic element 102 via a wire 22. The wire 22 is disposed on the upper surface of the relay substrate 50 and is covered with the insulating film 19 except the portion required for connection.

In the present disclosure, the entire MEMS acoustic element 202 including the circuit chip component 15 may be formed as an integrated package. In the present disclosure, the entire package can be miniaturized.

The first coating resin 71 may be electrically conductive. By adopting this configuration, the MEMS acoustic element 102 can be electromagnetically shielded. If the MEMS acoustic element 102 is electromagnetically shielded, the MEMS acoustic element 201 can be used even in an environment with high electromagnetic noise.

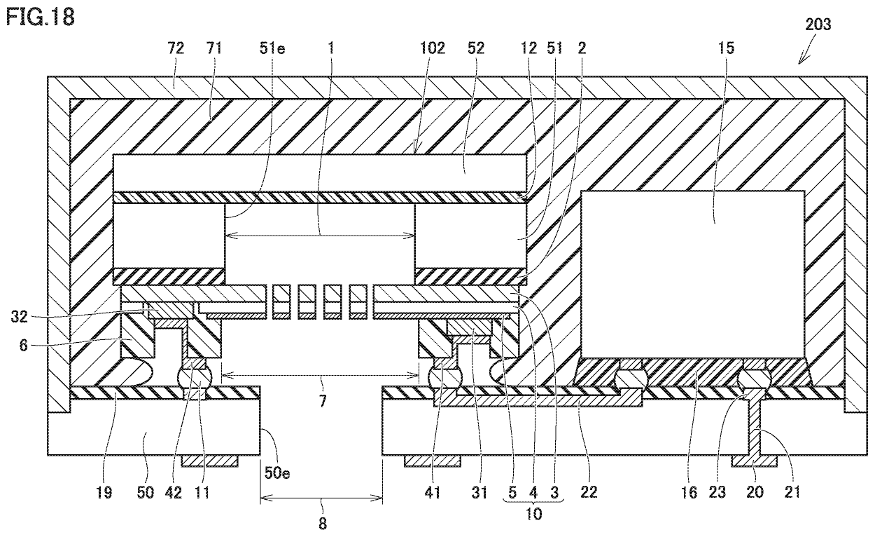

A MEMS acoustic element according to an aspect of the present disclosure will be described with reference to FIG. 18. FIG. 18 is a schematic cross-sectional view illustrating a MEMS acoustic element 203 according to the present disclosure.

The MEMS acoustic element 203 includes a second coating resin 72. The second coating resin 72 is disposed to cover a surface of the first coating resin 71 distant from the relay substrate 50 and a side surface thereof. The second coating resin 72 is electrically conductive. In the MEMS acoustic element 203, the first coating resin 71 is not electrically conductive. The other configurations are the same as those described above.

In the present disclosure, the entire MEMS acoustic element 203 including the circuit chip component 15 may be formed as an integrated package as described above.

In the present disclosure, since the second coating resin 72 is electrically conductive and is disposed to cover the first coating resin 71, the MEMS acoustic element 102 can be electromagnetically shielded. Therefore, the MEMS acoustic element 203 can be used even in an environment with high electromagnetic noise.

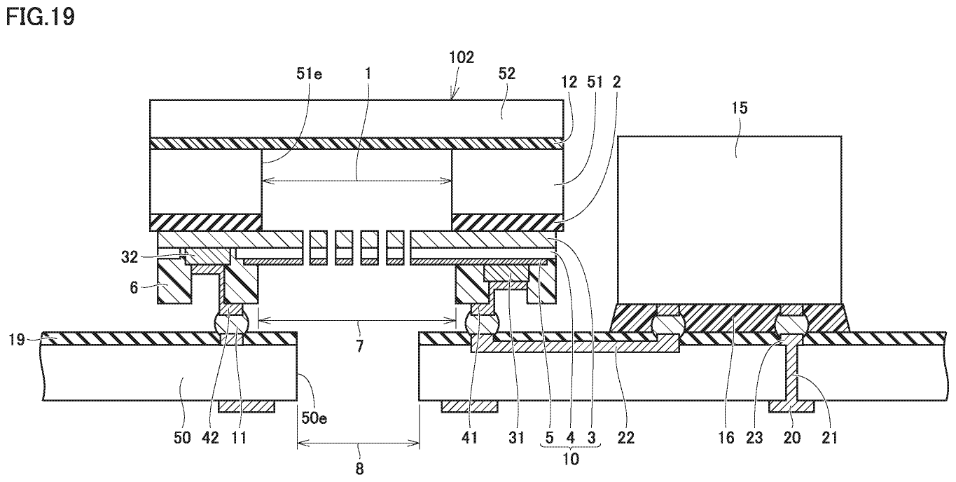

A manufacturing method of the MEMS acoustic element 203 according to the present disclosure will be described with reference to FIGS. 19 to 21.

In the present disclosure, in order to collectively obtain a plurality of MEMS acoustic elements, each step of the manufacturing method is performed using a substrate assembly having a size equivalent to a plurality of MEMS acoustic elements instead of a size equivalent to a single MEMS acoustic element.

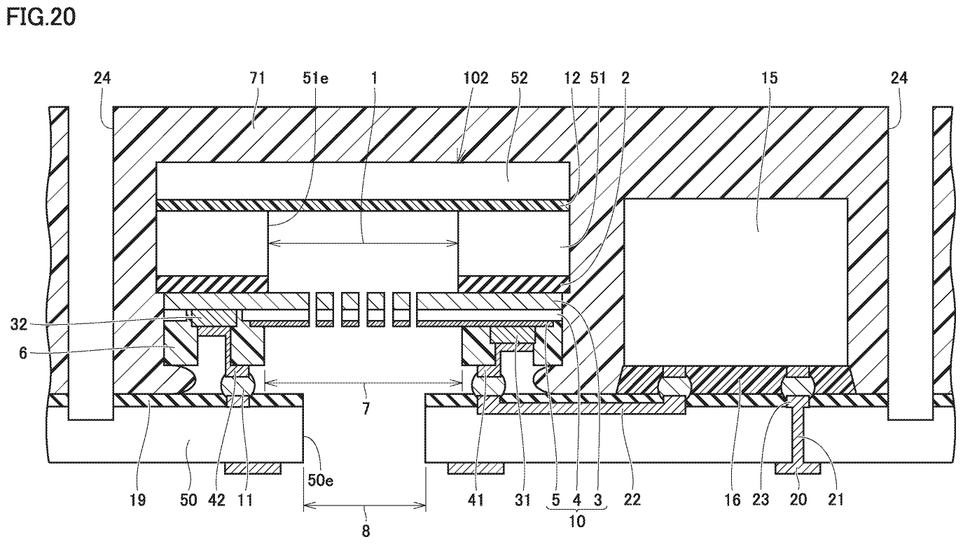

First, as illustrated in FIG. 19, the MEMS acoustic element 102 and the circuit chip component 15 are mounted on the upper surface of the relay substrate 50. Next, as illustrated in FIG. 20, the MEMS acoustic element 102 and the circuit chip component 15 on the upper surface of the relay substrate 50 are sealed with the first coating resin 71. Half cutting is performed by blade dicing. A groove 24 is formed by half cutting. The lower end of the groove 24 exceeds the insulating film 19 and reaches the relay substrate 50.

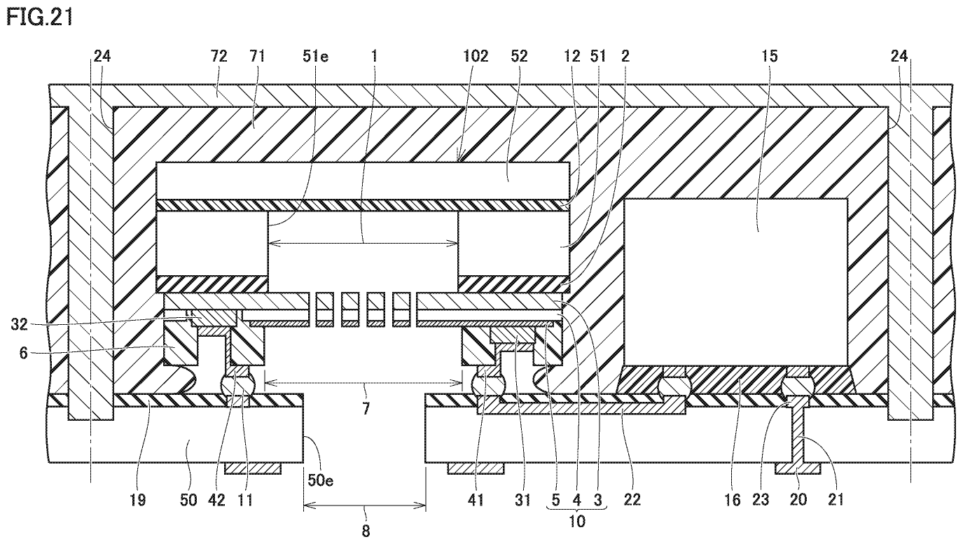

As illustrated in FIG. 21, a second coating resin 72 which is electrically conductive is disposed. The second coating resin 72 covers the upper surface of the first coating resin 71 and fills the groove 24. Thereafter, the substrate assembly is cut into individual products by blade dicing. Thus, the MEMS acoustic element 203 illustrated in FIG. 18 can be obtained.

The above-described aspect may be appropriately combined.

It should be understood that the aspects disclosed herein are illustrative and non-restrictive in all respects. The scope of the present disclosure is defined by the claims and includes any modifications within the scope and meaning equivalent to the claims.

In general, the description of the aspects disclosed should be considered as being illustrative in all respects and not being restrictive. The scope of the present disclosure is shown by the claims rather than by the above description and is intended to include meanings equivalent to the claims and all changes in the scope. While preferred aspects of the invention have been described above, it is to be understood that variations and modifications will be apparent to those skilled in the art without departing from the scope and spirit of the invention.

### DESCRIPTION OF REFERENCE SYMBOLS

1: cavity;
2: oxide film;
3: lower electrode layer (second electrode layer);
4: piezoelectric layer;
5: upper electrode layer (first electrode layer);
6: resin layer;
7: acoustic hole;
8: opening (of relay substrate);
10: vibration layer;
11: conductive connection member;
12: resin film;
14: slit;
15: circuit chip component;
16: underfill;
17, 21: connection conductor;
18, 20: pad electrode;
19: insulating film;
22: wire;
23: electrode;
24: groove;
31, 32: conductive layer;
40: ring-shaped metal layer;
41: first pad electrode;
42: second pad electrode;
50: relay substrate;
50e: second through hole;
51: first substrate;
51e: first through hole;
52: second substrate;
60: resin sheet;
61: first resin layer;
62: second resin layer;
71: first coating resin;
72: second coating resin;
101, 102, 103, 104: MEMS acoustic element.

1. A MEMS acoustic element comprising:
a first substrate provided with a first through hole;
a second substrate arranged adjacent to the first through hole and configured to partially overlap with the first substrate on a second side of the first substrate;
a vibration layer arranged adjacent to overlap with the first substrate on a first side of the first substrate opposite the second substrate and the second side of the first substrate, and configured to stride across the first through hole;
a resin layer disposed to overlap with a portion of the vibration layer overlapping with the first substrate;
a first pad electrode; and
a second pad electrode,
the first pad electrode and the second pad electrode being disposed on a surface of the resin layer opposite from the vibration layer.

2. The MEMS acoustic element according to claim 1, wherein the vibration layer includes:
a piezoelectric layer;
a first electrode layer disposed to overlap with a surface of the piezoelectric layer opposite from the first substrate; and
a second electrode layer disposed to overlap with a surface of the piezoelectric layer adjacent to the first substrate,
the first pad electrode being electrically connected to the first electrode layer, and
the second pad electrode being electrically connected to the second electrode layer.

3. The MEMS acoustic element according to claim 1, further comprising a ring-shaped metal layer disposed on a surface of the resin layer opposite from the vibration layer and configured to surround a projection region of the first through hole.

4. The MEMS acoustic element according to claim 1, further comprising:
a relay substrate provided with a second through hole that corresponds to the first through hole,
wherein the first pad electrode and the second pad electrode are each connected to the relay substrate via a conductive connection member.

5. The MEMS acoustic element according to claim 4, wherein an outer peripheral side surface of the resin layer, an outer peripheral side surface of the first substrate, an outer peripheral side surface of the second substrate, and a surface of the second substrate opposite from the first substrate are covered with a first coating resin.

6. The MEMS acoustic element according to claim 5, further comprising:
a circuit chip component mounted on a surface of the relay substrate adjacent to the first substrate,
wherein the circuit chip component is covered with the first coating resin.

7. The MEMS acoustic element according to claim 5, wherein the first coating resin is electrically conductive.

8. The MEMS acoustic element according to claim 6, further comprising a second coating resin configured to be electrically conductive and disposed to cover a surface of the first coating resin opposite from the relay substrate and a side surface of the first coating resin.

9. The MEMS acoustic element according to claim 1, wherein the second side of the first substrate and a side of second substrate are separate via a resin film.

10. The MEMS acoustic element according to claim 1, wherein the first side of the first substrate and vibration layer are separate via an oxide film.

11. A method of manufacturing a MEMS acoustic element comprising:
providing a first substrate with a first through hole and having a top side and a bottom side, the top side above the bottom side and on opposite sides of the first substrate;
disposing a second substrate below the first substrate and arranged to partially overlap a portion of the bottom side of the first substrate;
disposing a vibration layer above the top side of first substrate and arranged to partially overlap, and arranged to stride across the first through hole;
disposing a resin layer above the vibration layer and arranged to overlap with a portion of the vibration layer that overlaps with the first substrate;
disposing a first pad electrode above the vibration layer; and
disposing a second pad electrode above the vibration layer,
wherein the first pad electrode and the second pad electrode are disposed on a top surface of the resin layer.

12. The method of manufacturing according to claim 11,
wherein the vibration layer includes a piezoelectric layer, a first electrode layer, and a second electrode layer; and
wherein the method further includes:
disposing the first electrode layer above the piezoelectric layer and arranged to overlap the piezoelectric layer;
disposing the second electrode layer above the first substrate and below the piezoelectric layer and arranged to overlap the piezoelectric layer;
electrically connecting the first pad electrode to the first electrode layer; and
electrically connecting the second pad electrode to the second electrode layer.

13. The method of manufacturing according to claim 11, further comprising disposing a ring-shaped metal layer above the resin layer and arranged to surround a projection region of the first through hole.

14. The method of manufacturing according to claim 11, further comprising:
providing a relay substrate with a second through hole that corresponds to the first through hole; and
connecting the first pad electrode and the second pad electrode to the relay substrate via a conductive connection member.

15. The method of manufacturing according to claim 14, further comprising covering an outer peripheral side surface of the resin layer, an outer peripheral side surface of the first substrate, an outer peripheral side surface of the second substrate, and a surface of the second substrate with a first coating resin.

16. The method of manufacturing according to claim 15, further comprising:
mounting a circuit chip component on a surface of the relay substrate adjacent to the first substrate, and
covering the circuit chip component with the first coating resin.

17. The method of manufacturing according to claim 15, wherein the first coating resin is electrically conductive.

18. The method of manufacturing according to claim 16, further comprising disposing a second coating resin over the first coating resin and being electrically conductive.

19. The method of manufacturing according to claim 11, further comprising disposing a resin film between the first substrate and the second substrate.

20. The method of manufacturing according to claim 11, further comprising disposing an oxide film between the first substrate and the vibration layer.
